(19) United States
(12) Patent Application Publication
(10) Pub. No.: US 2026/0338171 A1
(43) Pub. Date: Oct. 29, 2026

(54) A CLOSED FLUID SYSTEM

(71) Applicant: APR Technologies AB, Enköping (SE)

(72) Inventors: Robert THORSLUND, Sigtuna (SE); Peter NILSSON, Sundbyberg (SE); Are BJÖRNEKLETT, Västerås (SE)

(21) Appl. No.: 19/471,726

(22) PCT Filed: Mar. 12, 2024
(86) PCT No.: PCT/SE2024/050223

§ 371 Date: Oct. 2, 2025

(30) Foreign Application Priority Data
Apr. 5, 2023 (SE) 2350402-0

(51) Int. Cl. F04B 11/00; F04B 19/20

(52) U.S. Cl. CPC F04B 11/00; F04B 19/20; F04B 2205/06

(57) ABSTRACT

Described is, among other things, a closed system (10) withholding a circulating fluid (20). A partially gas filled barrier bag (30) is located inside the closed system 5 to control expansion and or contraction of the fluid resulting from temperature variations.

### TECHNICAL FIELD

The present disclosure relates to a closed system housing a fluid. In particular the present disclosure relates to a closed system with a fluid at varying temperature where the fluid is circulated. The disclosure also extends to a thermal management system and to an expansion device.

### BACKGROUND

For many applications a closed system comprising a fluid is used. In a closed system housing a fluid, if the temperature rises, the fluid volume will expand and there is a risk of explosion or damage of parts in the system. If the temperature falls, vacuum pockets or undefined phases of the fluid and gas and the like can be formed which can reduce performance. This is particularly the case for circulated fluid systems such as thermal management systems where the system is designed to move heat from one place to another.

For example, in a heat controlling system such as the closed circulating system described in WO 2017/127017 the temperature may rise and fall during operation of the circulating system. Typically, the need to manage the expanding/contracting circulating fluid is solved by some kind of expansion device connected to the closed circulating system such as described in e.g., U.S. Pat. Nos. 6,119,951 and 5,456,409.

There is a constant desire to improve the operation of closed circulating systems housing/withholding a fluid. Hence, there exists a need for an improved circulating closed system withholding a fluid.

### SUMMARY

It is an object of the present invention to provide an improved closed circulating system withholding a fluid.

This object and/or others are, at least partly, obtained by the closed circulating system withholding a fluid as set out in the appended claims.

As has been realized by the inventors, existing solutions for compensating for volume changes of a fluid filled in a closed circulating system typically requires some external device for mitigating the varying volume of the fluid such as an external expansion device.

By placing at least one partially gas filled barrier bag in a closed circulating system withholding a fluid, the barrier bag can act as an internal expansion device and take care of the expansion/contraction of the fluid in that the barrier bag will vary its volume in response to the varying volume of the fluid in the closed system.

In accordance with one embodiment, a closed system withholding a fluid is provided. The system is configured to circulate the fluid, and a partially gas filled barrier bag is located inside the closed system to compensate for expansion and/or contraction of the fluid resulting from temperature variations. The barrier bag comprises at least two layers. Hereby the barrier bag can act to take up the volume differences in the fluid when the fluid expands/contracts due to temperature changes in the fluid and ensure that the barrier bag is not leaking gas over time.

In accordance with one embodiment, a plurality of barrier bags is located in the closed system. Hereby additional design possibilities for the closed system are achieved.

In accordance with one embodiment, the closed system is configured to circulate the fluid in an enclosed passage. The closed system can comprise at least two chambers. It is then possible to locate at least one barrier bag in each chamber whereby an efficient compensation for volume changes in the fluid can be achieved when a plurality of chambers is provided in the circulating system.

The use of barrier bags to control fluid volume changes can be particularly useful in circulating systems using a flow unit such as an electrohydrodynamic (EHD) pump an where the circulated fluid is a dielectric fluid.

In accordance with some embodiments, the barrier bag comprises at least two layers where one layer is a metal layer. Hereby the barrier bag can be made to have a long life-time. In particular the barrier bag can comprise at least three layers, comprising an inner polymer layer, a mid-metal layer and an outer polymer layer. Hereby a very robust structure for the barrier bag can be achieved that is suitable for many applications and in particular a pumped circulating system for thermal management.

In accordance with one advantageous embodiment, the barrier bag comprises a layered structure comprising an outer layer of Polyethylene terephthalate (PET) a mid-layer of aluminum (Al) and an inner layer of Polyethylene (PE) or Low-Density Polyethylene (LDPE).

In accordance with one embodiment, the barrier bag is formed as a bag having four welded sides. Hereby a robust, yet easy to produce barrier bag is provided.

In accordance with one embodiment, the barrier bag is provided with an anchor. Hereby the barrier bag can be easily secured inside the closed system.

In accordance with one embodiment, a cage is provided inside the closed system and a barrier bag or a plurality of barrier bags is/are located inside the cage. Hereby an alternative mechanism for holding the barrier bag in place is provided. The cage can be located outside the flow path of the circulated fluid of the closed system whereby the barrier bag will not influence the circulation negatively.

In accordance with another aspect of the invention, a thermal management system comprising the closed system as set out above is provided. The thermal management system can comprise a heat sink and or a heat generating device. Hereby the expansions/contractions in the fluid of the system withholding the fluid can be easily controlled when the heat of the heat sink and or heat generating device varies.

In yet another aspect a barrier bag suitable to act as an expansion device in accordance with the above is provided.

### BRIEF DESCRIPTION OF THE DRAWINGS

The present invention will now be described in more detail by way of non-limiting examples and with reference to the accompanying drawings, in which:

FIG. 1 is a view of a thermal management system comprising a closed system withholding a fluid,

FIG. 2 is a view of a closed system withholding a fluid circulated in the closed system,

FIG. 3 is a view of a closed system withholding a fluid circulated in the closed system in a closed loop,

FIG. 4, is a view of a closed system withholding a fluid circulated in the closed system where the closed system has a plurality of chambers,

FIG. 5 shows an exemplary structure for a barrier bag, and

FIG. 6 shows a barrier bag.

### DETAILED DESCRIPTION

The invention will now be described more fully hereinafter with reference to the accompanying drawings, in which certain embodiments of the invention are shown. The invention may, however, be embodied in many different forms and should not be construed as limited to the embodiments set forth herein; rather, these embodiments are provided by way of example so that this disclosure will be thorough and complete, and will fully convey the scope of the invention to those skilled in the art. For example, like or similar components of different embodiments can be exchanged between different embodiments. Some components can be omitted from different embodiments. Like numbers refer to like elements throughout the description.

In the below description a system filled with a fluid is described. The system is a closed system. The fluid can typically be a liquid, but other fluids are also envisaged. The system can be a closed loop system wherein a flow of a circulating fluid, such as a thermal management liquid is circulated. The flow can in accordance with some embodiments be regulated by means of a flow unit controlling the flow. In some embodiments the closed system can be designed to allow for a circulation of a fluid without the provision of a dedicated flow unit that propels the flow in the closed system (a self-propelling system).

It is to be understood that the features from different embodiments can be combined and that no feature of an embodiment is essential unless explicitly so expressed. Hence, the person skilled in the art can select which features and dimensions that are deemed to be advantageous for a particular implementation.

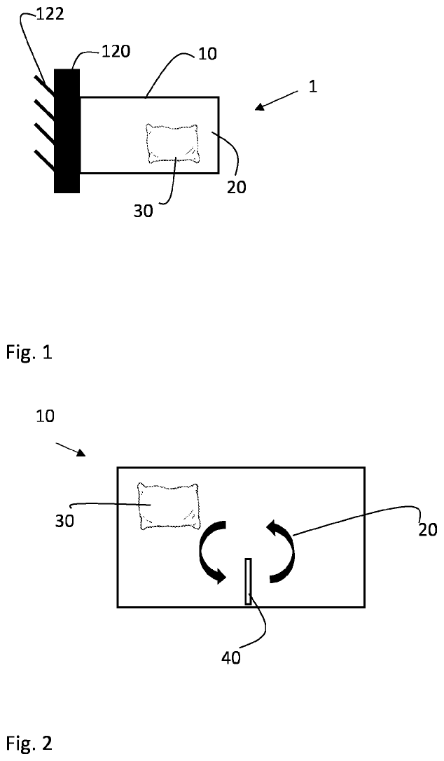

In FIG. 1, a general view of a thermal management system 1 is shown. The thermal management system 1 comprises closed system 10 comprising a fluid 20 therein. The closed system 10 is completely sealed so that no gas or fluid can enter/exit the closed system 10 in an uncontrolled manner. The closed 10 system can be subject to different changes in temperature. For example, the system can be heated (or cooled) by some external device 120, such as a heat sink or a heat generating device. In FIG. 1, the external device is exemplified by a heat sink 120 having flanges 122. Thus, the closed system 10 can be used in some type of heat regulating application such as a thermal management system 1 where the closed system is used as the control mechanism for controlling heat and heat dissipation. In accordance with some other embodiments the ambient temperature of the closed system 10 fluctuates so that the temperature of the fluid inside the closed system 10 varies.

Regardless of the type of application, if the closed system 10 is completely filled with fluid at a particular temperature, a temperature increase of the fluid 20 will increase the pressure inside the closed system 10 and parts inside the closed system risk being damaged. Similarly, a decrease in temperature will cause the fluid to contract and vacuum pockets and the like can form which can be undesired.

The closed system 10 filled with the fluid 20 further has at least one partially gas filled barrier bag 30 located therein. The barrier bag 30 is a bag that can change the volume that it occupies by being formed by an elastic material. The barrier bag can be formed in different ways, for example in accordance with one embodiment three sides of a bag can be impulse heat weld creating an open bag container. Next, an in-situ gas filling of the bag is performed and finally the fourth, open, side of the bag is welded to close the bag with gas therein. Typically, but not required to the bag is partly filled with a known and pure gas, for example Air, Nitrogen or Argon. The amount of gas to be filled within the enclosed volume of the bag is determined by the overall fluid system parameters and the size of the bag. Typically, the fluid volume expansion and contraction over the fluid systems temperature operating range is determined. Based on such a determined fluid volume expansion and contraction, the dimensions of the barrier bag and the amount of gas filled in the bag is determined. This can for example be performed by looking on the allowed over and under pressure in the fluid system, for example the barrier bag can be filled between 5-95% of its non-pressurized initial volume. The barrier bag is then sealed. Typically, the barrier bag can be immediately seam sealed using for example an impulse welder, closing the bag. The at least one barrier bag 30 has the function of compensating for temperature changes that makes the volume of the fluid 20 inside the closed system 10 change. Thus, the partially gas filled barrier bag 30 acts as an internal expansion device to compensate for the temperature variations causing a volume variation of the fluid 20.

The barrier bag 30 is advantageously a bag designed to withhold a gas for a very long time, typically at least the expected life time of the system. When the circulating fluid expands, the gas in the barrier bag 30 located in contact with the fluid is pressurized and vice versa whereby the varying temperature can be mitigated in a cost-efficient manner in that the barrier bag absorbs the changing volume of the fluid 20 in the closed system 10.

In FIG. 2 another example of a closed system 10 comprising a fluid 20 is depicted. The closed system 10 of FIG. 2 comprises a flow unit 40 driving a flow for circulating the fluid 20 inside the closed system 10. The flow is indicated by the arrows in FIG. 2.

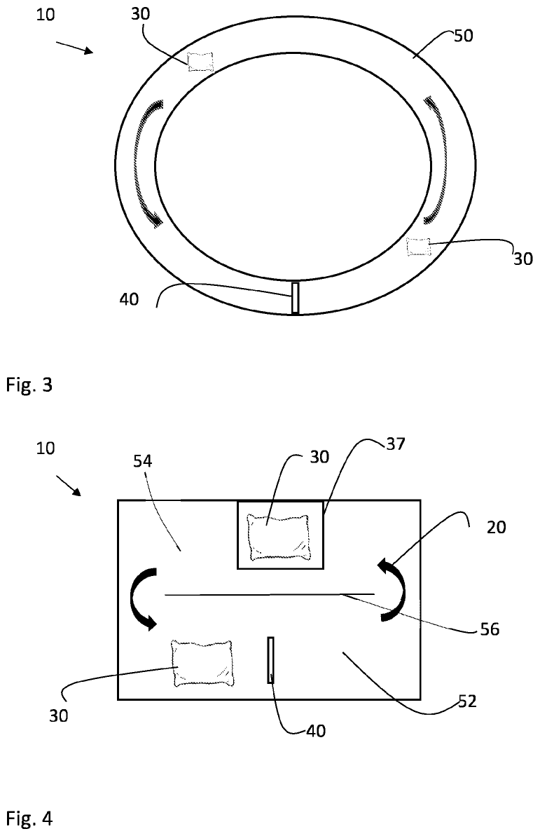

In accordance with one embodiment, the closed system is formed by or comprises an enclosed passage that is adapted to convey a circulating fluid. The enclosed passage may for example, define a closed loop in which the fluid 20 may circulate. Such a configuration is shown in FIG. 3 where a flow unit 40 drives a flow to circulate in an enclosed passage 50. In some embodiments more than one flow unit 40 is provided. It is also envisaged that the flow in the enclosed passage 50 can be driven without a flow unit 40 such as by temperature variations.

The flow unit 40 can be any type of device promoting a circulation of the fluid. In accordance with one embodiment the flow unit is a mechanical pump. In accordance with another embodiment, the flow unit is an electrohydrodynamic (EHD) pump. The EHD pump make a dielectric fluid, typically ionized particles or molecules of the fluid 20, interact with an electric field and thereby drive a flow. The EHD pump can comprise a first electrode and a second electrode, wherein the second electrode is offset from the first electrode in a downstream direction of a flow of the circulating fluid. The first electrode and the second electrode are connectable to a voltage source. According to one embodiment, the first electrode is formed as a grid structure allowing the circulating fluid to flow through the first electrode. Further, multiple barrier bags 30 can be provided in the closed system 10 as seen in FIG. 3.

In FIG. 4 yet another embodiment with a circulating fluid 20 is depicted. According to the embodiment depicted in FIG. 4, the enclosed passage 50 is defined by at least a first chamber 52 and a second chamber 54 that are separated from each other. For example, a dividing wall 56 or septum can be used to separate the at least two chambers 52, 54. The dividing wall 56 may comprise gaps or local passages connecting the first chamber 52 and the second chamber 54 with each other, thereby defining a closed loop in which the fluid may circulate. The fluid may circulate through the first chamber 52, enter the second chamber 54 via one of the gaps in the dividing wall 56, pass through the second chamber 54 and re-enter the first chamber 52 via a second gap in the wall 56. The circulating fluid is indicated by arrows in FIG. 4.

At least one of the chambers, 52, 54 such as the first chamber 52 may comprise a flow unit 40 as described above. The flow unit 40 may be configured to induce a flow in the fluid when operated in the activated state, and to impede or reduce a flow in the fluid when operated in a deactivated state. For example, when the flow unit 40 is an EHD pump, the voltage difference can be reduced as compared to the activated state. Thus, the flow unit 40 may be used for affecting or controlling the circulation of the fluid between the first chamber 52 and the second chamber 54. In accordance with some embodiments, multiple barrier bags 30 can be provided when multiple chambers 52, 54 are provided. In accordance with one embodiment at least one barrier bag is located in each of the chambers 52, 54.

Further, as can be seen in FIG. 4, the barrier bag 30, can be secured inside the closed system 10. Thus, in some applications or configurations including all configurations described herein, the barrier bag 30 can be held in place inside the closed system. In accordance with some embodiments the barrier bag can be placed in a cage 37 inside the closed system. The cage 37 can be located at any suitable location inside the closed system. In accordance with one embodiment the cage is located at a location outside the circulating flow of the closed system. Hereby the flow is not impacted by the cage 37 or the barrier bag 30. The cage can be formed in some suitable manner and has at least one port acting as an inlet/outlet via which port fluid of the closed system can enter or exit the cage.

Other securing methods can also be used to hold the barrier bag 30 in place such as anchoring the barrier bag or providing a holder. The holder can be made of a plastics material or a metal material. For example, the holder can be shaped as a hook and secured inside the closed system to hold the barrier bag in place. In accordance with some embodiments a cavity is formed inside the closed system where the barrier bag 30 can be placed. However, it is also envisaged that in some applications, the barrier bag does not need to be secured by any special securing device, but can float free inside the closed system 10.

The barrier bag 30 can be any suitable barrier bag meeting the requirement of securely holding the gas for the required time under given conditions. The barrier bag 30 typically has a plurality of layers (at least two layers) to ensure that the gas is kept withing the barrier bag 30 for a long time and that the bag is mechanically rigid and that the bag is compatible with the sealing method of choice, typically but not limited to pulse welding heat sealing. The different layers of the barrier bag have different purposes, typically but not limited to a suitable barrier bag for the application can consist of three layers. Such a three-layer structure can be formed by an inner polymer layer, a mid-metal layer and an outer polymer layer. Additional or fewer layers can be used depending on the application. At least one of the layers is advantageously a metal layer.

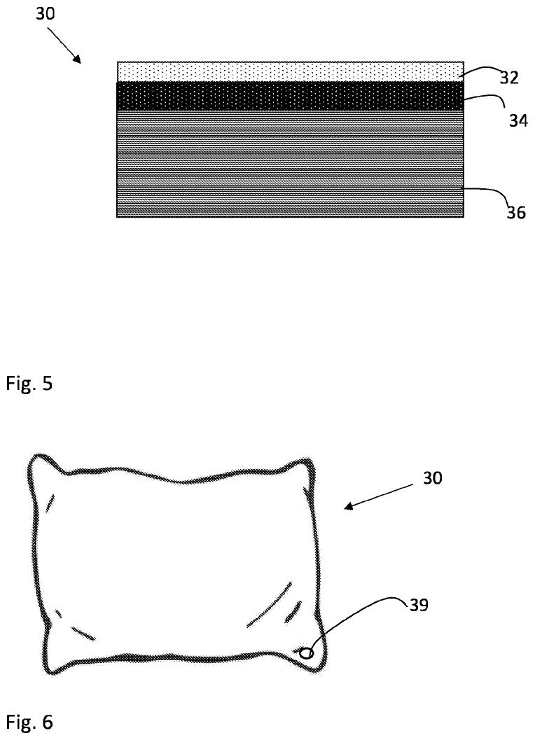

In accordance with one embodiment, the barrier bag 30 is formed by a layered structure comprising an outer layer of Polyethylene terephthalate (PET) a mid-layer of aluminum (Al) and an inner layer of Polyethylene (PE) or Low-Density Polyethylene (LDPE). Such a layered structure is depicted in FIG. 5. The outer layer 32 is the layer facing the fluid is a barrier layer but this outer layer can also act also to protect the second, mid layer 34, The mid layer 34 acts as a gas and fluid sealant and has properties for preventing diffusion. The third layer 36, the inner layer, is a layer that is weldable and that can be used to create the seam weld. The inner layer 36 can also act to protects the mid layer and can add rigidity to the barrier bag wall. In accordance with one embodiment, the barrier bag 30 is formed by a thin layer of PET (about 5-20 or 12 micro meters), a thin layer of Al (about 10-30 or 18 micro meters) and a thicker layer of PE or LDPE (about 20-200 micro meters or 100 micro meters). The exemplary structure of a barrier bag 30 shown in FIG. 5 has a plurality of layers and is seen in a cross-section from the side. In the exemplary embodiment of FIG. 5, an outer layer 32 of PET 12 is provided. Further, a mid-layer 34 of Al 18 and an inner layer 36 of PE 100 is provided.

In FIG. 6, a barrier bag 30 is depicted. The barrier bag 30 is here provided with an anchor 39. The anchor 39 can be used to secure the barrier bag inside the closed system. For example, the anchor 39 can be attached to a connector such as a holder inside the closed system. The anchor 39 can be formed as hole punched in the barrier bag outside the sealed perimeter of the barrier bag 30. For example, a hole 39 can be located outside a welded seam of the barrier bag 30. The barrier bag 30 can then be secured inside the closed system 10 by providing a hook or the like inside the closed system to which hook the barrier bag 30 can be attached. Such a hook can be located outside the flow in a circulating closed system so as to not impact the flow itself.

The use of a gas filled barrier bag in a closed fluid system is advantageous in many types of products. For example, in high volume products due to its inherent ease and low cost of production. Also, the barrier bag is advantageous is fluid systems with irregular shape or other constraints on the size or placement of already known solutions to the fluid expansion problem in a closed fluid system due to the capability of the barrier bag to be formed in many different ways, it can be formed very small, thin, round, square, etc. The barrier bag in closed fluid systems can for example be used in heat generating electronic devices such as battery modules for cars, heavy equipment, peak shaving, energy storage. It can also be used in applications such as electronic devices attached to heat sinks, finned heatsinks with forced or natural air convection cooling. Also, it can be used in telecommunication equipment, information and communications technology, and in similar applications.

1. A closed system (10) withholding a fluid (20) the system being configured to circulate the fluid, wherein a partially gas filled barrier bag (30) is located inside the closed system to compensate for expansion and/or contraction of the fluid resulting from temperature variations, wherein the barrier bag comprises at least two layers (32, 34, 36).

2. The closed system according to claim 1, wherein a plurality of barrier bags (30) is located in the closed system.

3. The closed system according to claim 1, wherein the closed system is configured to circulate the fluid in an enclosed passage (50).

4. The closed system according to claim 1, wherein the closed system comprises at least two chambers (52, 54).

5. The closed system according to claim 4, wherein at least one barrier bag (30) is located in each chamber (52, 54).

6. The closed system according to claim 1, wherein the fluid is circulated using a flow unit (40).

7. The closed system according to claim 6, wherein the flow unit (40) is an electrohydrodynamic (EHD) pump.

8. The closed system according to claim 7, wherein the circulated fluid is a dielectric fluid.

9. The closed system according to claim 1, wherein the barrier bag comprises at least one-metal layer (34).

10. The closed system according to claim 9, wherein the barrier bag comprises at least three layers (32, 34, 36), comprising an inner polymer layer (36), a mid-metal layer (34) and an outer polymer layer (32).

11. The closed system according to claim 10, wherein the barrier bag comprises a layered structure comprising an outer layer of Polyethylene terephthalate (PET) a mid-layer of aluminum (Al) and an inner layer of Polyethylene (PE) or Low-Density Polyethylene (LDPE).

12. The closed system according to claim 1, wherein the barrier bag is filled with gas corresponding to between 5-95% of its non-pressurized initial volume.

13. The closed system according to claim 1, wherein the barrier bag is formed as a bag having four welded sides.

14. The closed system according to claim 1, wherein the barrier bag is provided with an anchor (39).

15. The closed system according to claim 1, further comprising a cage (37), and wherein the barrier bag is located inside the cage.

16. The closed system according to claim 15, wherein the cage (37) is located outside the flow path of the circulated fluid.

17. A thermal management system (1) comprising the closed system according to claim 1.

18. The thermal management system according to claim 17, further comprising a heat sink (120) and/or a heat generating device (120).

19. A partially gas filled barrier bag (30) comprising at least two layers (32, 34, 36), for use as an expansion device in a closed system withholding a circulating fluid, wherein the barrier bag is formed as a bag having four welded sides, the partially gas filled barrier bag (30) being sealed and filled with gas corresponding to between 5-95% of its non-pressurized initial volume.

20. The partially gas filled barrier bag (30) according to claim 19, wherein the barrier bag is provided with an anchor (39).

21. The partially gas filled barrier bag (30) according to claim 20, wherein the anchor (39) comprises a hole punched in the barrier bag outside a sealed perimeter of the barrier bag (30).
